(19) United States
(12) Patent Application Publication
(10) Pub. No.: US 2025/0343482 A1
(43) Pub. Date: Nov. 6, 2025

(54) LOW-DROPOUT REGULATOR CIRCUIT WITH ADAPTIVE TRANSISTOR WELL SWITCHING

(71) Applicant: QUALCOMM Incorporated, San Diego, CA (US)

(72) Inventor: Hua GUAN, San Diego, CA (US)

(21) Appl. No.: 18/654,661

(22) Filed: May 3, 2024

(51) Int. Cl. H02M 3/158; G05F 1/59; H02M 1/00; H03K 19/21

(52) U.S. Cl. CPC H02M 3/158; G05F 1/59; H02M 1/0045; H03K 19/215

(57) ABSTRACT

Techniques and apparatus for supplying power in a low-dropout (LDO) regulator circuit are provided. One example LDO regulator circuit generally includes a first input, a second input, an output, a first pass transistor, and a second pass transistor. The first pass transistor has a switchable well, a source coupled to the first input of the LDO regulator circuit, and a drain coupled to the output of the LDO regulator circuit. The second pass transistor has a switchable well, a source coupled to the second input of the LDO regulator circuit, and a drain coupled to the output of the LDO regulator circuit.

### TECHNICAL FIELD

Certain aspects of the present disclosure generally relate to electronic circuits and, more particularly, to a power supply circuit and techniques for voltage regulation.

### BACKGROUND

A voltage regulator ideally provides a constant direct current (DC) output voltage regardless of changes in load current or input voltage. Voltage regulators may be classified as either linear regulators or switching regulators. While linear regulators tend to be small and compact, many applications may benefit from the increased efficiency of a switching regulator. A linear regulator may be implemented by a low-dropout (LDO) regulator, for example. A switching regulator (also known as a “switching converter” or “switcher”) may be implemented, for example, by a switched-mode power supply (SMPS), such as a buck converter, a boost converter, a buck-boost converter, or a charge pump.

Power management integrated circuits (power management integrated circuits (ICs) or PMICs) are used for managing the power demands of a host system and may include and/or control one or more voltage regulators (e.g., boost converters). A PMIC may be used in battery-operated devices, such as mobile phones, tablets, laptops, wearables, etc., to control the flow and direction of electrical power in the devices. The PMIC may perform a variety of functions for the device such as DC-to-DC conversion, voltage regulation, battery charging, power-source selection, voltage scaling, power sequencing, etc. For example, a PMIC may feature an LDO regulator for voltage regulation.

### SUMMARY

The systems, methods, and devices of the disclosure each have several aspects, no single one of which is solely responsible for its desirable attributes. Without limiting the scope of this disclosure as expressed by the claims that follow, some features will now be discussed briefly. After considering this discussion, and particularly after reading the section entitled “Detailed Description,” one will understand how the features of this disclosure provide the advantages described herein.

Certain aspects of the present disclosure provide a low-dropout (LDO) regulator circuit. The LDO regulator circuit generally includes a first input, a second input, an output, a first pass transistor, and second pass transistor. The first pass transistor includes a switchable well, a source coupled to the first input of the LDO regulator circuit, and a drain coupled to the output of the LDO regulator circuit. The second pass transistor includes a switchable well, a source coupled to the second input of the LDO regulator circuit, and a drain coupled to the output of the LDO regulator circuit.

Certain aspects of the present disclosure are directed to a method of supplying power. The method generally includes (i) regulating an output voltage via a first pass transistor of an LDO regulator circuit in a first scenario, the first pass transistor including a switchable well and being coupled between a first input and an output of the LDO regulator circuit and (ii) regulating the output voltage via a second pass transistor of the LDO regulator circuit in a second scenario, the second pass transistor including a switchable well and being coupled between a second input and the output of the LDO regulator circuit.

Certain aspects of the present disclosure provide a wireless device including the power supply circuit described herein.

Certain aspects of the present disclosure provide a wearable device including the power supply circuit described herein.

Certain aspects of the present disclosure provide an Internet of Things (IoT) device including the power supply circuit described herein.

Certain aspects of the present disclosure provide an integrated circuit (IC) including the power supply circuit (or at least a portion of the power supply circuit) described herein.

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

### BRIEF DESCRIPTION OF THE DRAWINGS

So that the manner in which the above-recited features of the present disclosure can be understood in detail, a more particular description, briefly summarized above, may be had by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects.

FIG. 1 is a block diagram of an example device that includes a voltage regulator, in which aspects of the present disclosure may be implemented.

FIG. 2 is a block diagram of an example power supply circuit that includes a low-dropout (LDO) regulator circuit, in accordance with certain aspects of the present disclosure.

FIG. 3 is a circuit diagram of an example power supply circuit that includes the LDO regulator circuit of FIG. 2, in accordance with certain aspects of the present disclosure.

FIG. 4A is a circuit diagram of an example logic circuit included in the LDO regulator circuit of FIG. 3, in accordance with certain aspects of the present disclosure.

FIG. 4B illustrates a table that displays the operation of the logic circuit of FIG. 4A in different scenarios, in accordance with certain aspects of the present disclosure.

FIG. 5 is a flow diagram illustrating example operations for supplying power, in accordance with certain aspects of the present disclosure.

To facilitate understanding, identical reference numerals have been used, where possible, to designate identical elements that are common to the figures. It is contemplated that elements disclosed in one aspect may be beneficially utilized on other aspects without specific recitation.

### DETAILED DESCRIPTION

Certain aspects of the present disclosure provide techniques and apparatus for supplying power using a linear voltage regulator circuit (e.g., a low-dropout (LDO) regulator circuit) with adaptive switching. Such an LDO regulator circuit may include a first power supply path from a first input (e.g., for coupling to a first power supply circuit) through a first pass transistor to an output of the LDO regulator circuit and a second power supply path from a second input (e.g., for coupling to a second power supply circuit) through a second pass transistor to the output. The adaptive switching of the LDO regulator circuit may involve adaptive well switching (e.g., selectively using body diodes included in the pass transistors to block current between one of the two inputs and the output of the LDO regulator circuit) and adaptive transistor switching (e.g., selectively using a controller to drive one of the pass transistors and choose the first power supply path or the second power supply path) based on the voltages at the first and second inputs and the desired regulated voltage at the output.

Various aspects of the disclosure are described more fully hereinafter with reference to the accompanying drawings. This disclosure may, however, be embodied in many different forms and should not be construed as limited to any specific structure or function presented throughout this disclosure. Rather, these aspects are provided so that this disclosure will be thorough and complete, and will fully convey the scope of the disclosure to those skilled in the art. Based on the teachings herein one skilled in the art should appreciate that the scope of the disclosure is intended to cover any aspect of the disclosure disclosed herein, whether implemented independently of or combined with any other aspect of the disclosure. For example, an apparatus may be implemented or a method may be practiced using any number of the aspects set forth herein. In addition, the scope of the disclosure is intended to cover such an apparatus or method which is practiced using other structure, functionality, or structure and functionality in addition to or other than the various aspects of the disclosure set forth herein. It should be understood that any aspect of the disclosure disclosed herein may be embodied by one or more elements of a claim.

The word “exemplary” is used herein to mean “serving as an example, instance, or illustration.” Any aspect described herein as “exemplary” is not necessarily to be construed as preferred or advantageous over other aspects.

As used herein, the term “connected with” in the various tenses of the verb “connect” may mean that element A is directly connected to element B or that other elements may be connected between elements A and B (i.e., that element A is indirectly connected with element B). In the case of electrical components, the term “connected with” may also be used herein to mean that a wire, trace, or other electrically conductive material is used to electrically connect elements A and B (and any components electrically connected therebetween).

### An Example Device

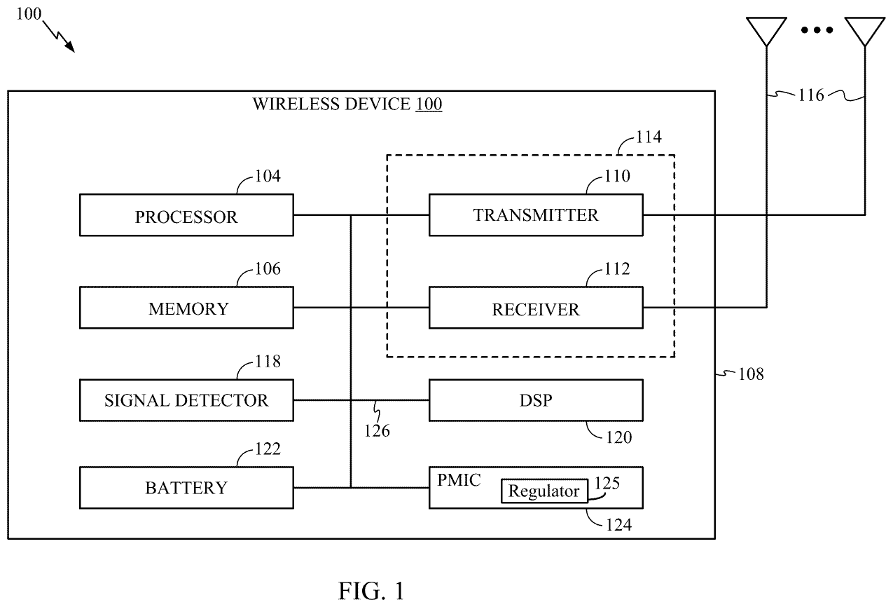

FIG. 1 illustrates an example device 100, in which aspects of the present disclosure may be implemented. The device 100 may be a battery-operated device such as a cellular phone, a personal digital assistant (PDA), a handheld device, a wireless modem, a smartphone, a tablet, a laptop computer, a personal computer, a wearable device, an Internet of Things (IoT) device, an augmented reality device, etc. The device 100 is an example of a device that may be configured to implement the various systems and methods described herein.

The device 100 may include a processor 104 which controls operation of the device 100. The processor 104 may also be referred to as a central processing unit (CPU). Memory 106, which may include both read-only memory (ROM) and random access memory (RAM), provides instructions and data to the processor 104. A portion of the memory 106 may also include non-volatile random access memory (NVRAM). The processor 104 typically performs logical and arithmetic operations based on program instructions stored within the memory 106. The instructions in the memory 106 may be executable to implement the methods described herein.

The device 100 may also include a transmitter 110 and/or a receiver 112 to allow transmission and/or reception, respectively, of data between the device 100 and a remote location. In some cases, the transmitter 110 and receiver 112 may be combined into a transceiver 114. One or more antennas 116 may be attached or otherwise coupled to a housing 108 of the device 100 and electrically coupled to the transceiver 114. For certain aspects, the device 100 may also include multiple transmitters, multiple receivers, and/or multiple transceivers (not shown).

The device 100 may also include a signal detector 118 that may be used in an effort to detect and quantify the level of signals received by the transceiver 114. The signal detector 118 may detect such signals as total energy, energy per subcarrier per symbol, and power spectral density, among others. The device 100 may also include a digital signal processor (DSP) 120 for use in processing signals.

The device 100 may further include a battery 122, which may be used to power the various components of the device 100 (e.g., when another power source—such as a wall adapter or a wireless power charger—is unavailable). The battery 122 illustrated in FIG. 1 may represent multiple portable power sources, such as a main battery and a backup battery (or a supercapacitor). In some cases, the battery 122 may be rechargeable.

The device 100 may also include a power management integrated circuit (IC) (or PMIC) 124 for managing the power from the battery 122 (or batteries), a wall adapter, and/or a wireless power charger to the various components of the device 100. The PMIC 124 may perform a variety of functions for the device such as DC-to-DC conversion, voltage regulation (e.g., with a voltage regulator 125), battery charging, power-source selection, voltage scaling, power sequencing, etc. In certain aspects, the voltage regulator 125 may be implemented with an LDO regulator circuit with adaptive switching, as described herein.

The various components of the device 100 may be coupled together by a bus system 126. The bus system 126 may include a power bus, a control signal bus (e.g., system power management interface (SPMI) or inter-integrated circuit (I²C) bus), and/or a status signal bus in addition to a data bus. Additionally or alternatively, various combinations of the components of the device 100 may be coupled together by one or more other suitable techniques.

### Example Voltage Regulator with Adaptive Switching

Voltage regulators (e.g., LDO regulators) used in devices often use different voltages for different modes and/or use cases. For example, a device may include a universal subscriber identity module (USIM) and/or a secure digital (SD) card, and different generations of USIMs and SD cards may use different power supply voltages. The voltage regulator(s) in the device may be configured to support multiple generations of USIMs and SD cards (using different power supply voltages). In another example, a device may include a camera driver that uses a dynamic power supply voltage depending on the mode of the camera. The voltage regulator(s) in the device may be configured to support multiple camera modes (using different power supply voltages).

However, voltage regulators may often share input voltages with other loads of a device and struggle to support different loads (or the same load in a different use case) efficiently, especially as the difference between an input voltage and an output voltage of a voltage regulator increases (resulting in increased power loss). As a result, a voltage regulator may suffer from poor efficiency, which may affect the battery life of the device and/or cause thermal issues.

To overcome these challenges, certain aspects of the present disclosure provide a multi-input, single-output LDO regulator circuit with adaptive switching based on the voltages at first and second inputs of the LDO regulator circuit and the desired regulated voltage at an output of the LDO regulator circuit. By utilizing adaptive switching (e.g., adaptive transistor well switching and adaptive transistor switching), the LDO regulator circuit may be capable of achieving greater power efficiency (e.g., extending the battery life of a device that includes the LDO regulator circuit), may successfully block currents in the forward or reverse directions, may occupy less area compared to other multi-input, single-output LDO regulator circuits using at least one additional transistor for providing a blocking diode, and may have improved thermal performance (e.g., operate with reduced heat dissipation).

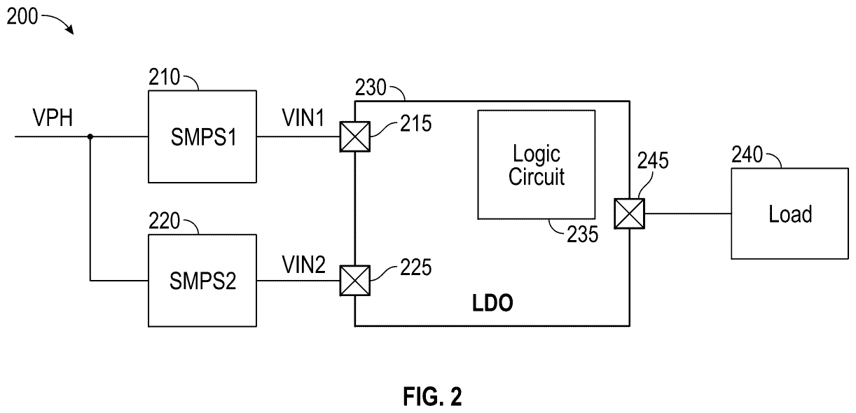

FIG. 2 is a block diagram of an example power supply circuit 200 that includes an LDO regulator circuit 230, in accordance with certain aspects of the present disclosure. The LDO regulator circuit 230 may be referred to herein as a dual-input, single-output (DISO) LDO regulator circuit and is thus labeled “DISO LDO” in FIG. 2. In addition to the LDO regulator circuit 230, the power supply circuit 200 may include a first switched-mode power supply 210 (labeled “SMPS1”) or linear regulator, and a second switched-mode power supply 220 (labeled “SMPS2”) or linear regulator. The power supply circuit 200 may be used to supply power to a load 240. The load 240 may represent one or more circuits of a device (e.g., the device 100) that are powered by the power supply circuit 200.

An input of the SMPS1 210 and an input of the SMPS2 220 may be coupled to a power supply rail (labeled “VPH”) which may, for example, be coupled to a battery (e.g., battery 122) of a device (e.g., device 100 of FIG. 1), a wall adapter, and/or a wireless power charger. An output of the SMPS1 210 may be coupled to an input 215 (labeled “VIN1”) of the LDO regulator circuit 230, and an output of the SMPS2 220 may be coupled to another input 225 (labeled “VIN2”) of the LDO regulator circuit 230, as illustrated. Each of the SMPS1 210 and the SMPS2 220 may be implemented as a buck converter, a boost converter, a buck-boost converter, or a charge pump, for example. The LDO regulator circuit 230 may include a logic circuit 235, and the logic circuit 235 may be configured to facilitate the adaptive switching described herein. An output 245 of the LDO regulator circuit 230 may be coupled to the load 240.

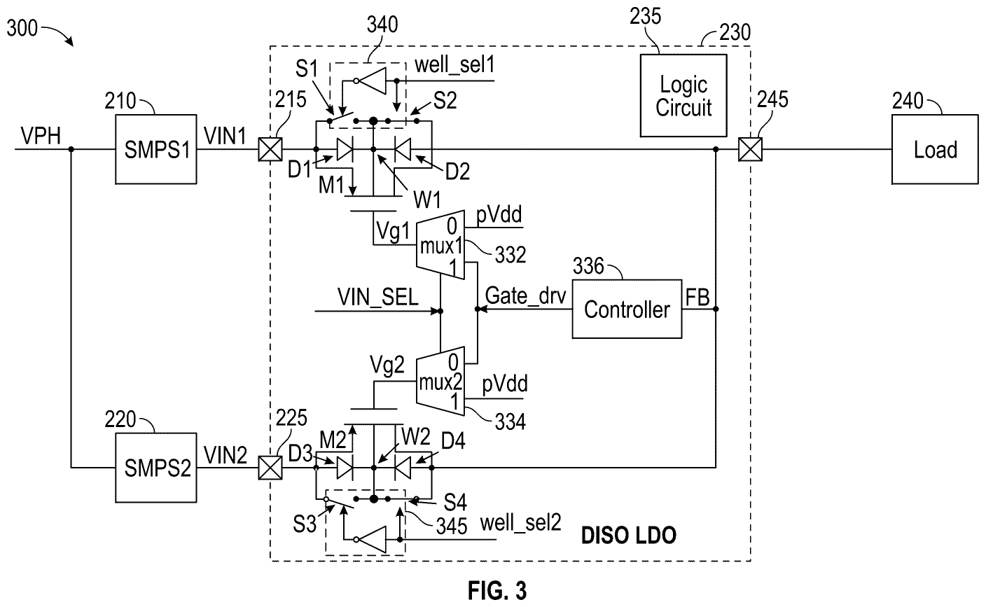

FIG. 3 is a circuit diagram of an example power supply circuit 300 that includes the LDO regulator circuit 230 of FIG. 2, in accordance with certain aspects of the present disclosure. The power supply circuit 300 may be similar to the power supply circuit 200 and may include the SMPS1 210 (or a linear regulator) and the SMPS2 220 (or a linear regulator), as illustrated. In addition to the logic circuit 235, the LDO regulator circuit 230 may also include transistor M1 (e.g., p-type metal-oxide-semiconductor field-effect transistor (MOSFET), also referred to as a PMOS transistor), transistor M2 (e.g., a p-type MOSFET), a first multiplexer 332 (labeled “mux1”), a second multiplexer 334 (labeled “mux2”), and a controller 336. For other aspects, the multiplexers 332, 334, and/or the logic circuit 235 may be part of the control logic for the LDO regulator circuit 230 (e.g., part of controller 336), which this encompassing control logic may be referred to simply as a logic circuit for the LDO regulator circuit. Transistors M1 and M2 may both function and be referred herein to as pass transistors of the LDO regulator circuit 230.

Pass transistor M1 may include a switchable well 340, a source coupled to the input 215 of the LDO regulator circuit 230, and a drain coupled to the output 245 of the LDO regulator circuit 230, as illustrated. As illustrated, the switchable well 340 may include switches S1 and S2 and a logic inverter having an input coupled to a control input of switch S2 and an output coupled to a control input of switch S1. In response to a logic low at a control input (labeled “well_sel1”) of the switchable well 340, the switchable well 340 may close a switch S1 between the source and a well W1 of transistor M1 and open a switch S2 between the drain and the well W1 of transistor M1. In this manner, a body diode D2 of transistor M1 with a cathode coupled to the well W1 and an anode coupled to the drain of transistor M1 may be effectively present in transistor M1, and a body diode D1 may be shorted (e.g., effectively removing body diode D1 from the transistor M1 by shorting the well W1 to the source of transistor M1). In response to a logic high at well_sel1 of the switchable well 340, the switchable well 340 may open switch S1 and close switch S2. In this manner, the body diode D1 of transistor M1 with a cathode coupled to the well W1 and an anode coupled to the source of transistor M1 may be effectively present in transistor M1 and body diode D2 may be shorted (e.g., effectively removing body diode D2 from the transistor M1 by shorting the well W1 to the drain of transistor M1).

Pass transistor M2 may include a switchable well 345, a source coupled to the second input 225 of the LDO regulator circuit 230, and a drain coupled to the output 245 of the LDO regulator circuit 230, as illustrated. As illustrated, the switchable well 345 may include switches S3 and S4 and a logic inverter having an input coupled to a control input of switch S4 and an output coupled to a control input of switch S3. In response to a logic low at a control input (labeled “well_sel2”) of the switchable well 345, the switchable well 345 may close a switch S3 between the source and a well W2 of transistor M2 and open a switch S4 between the drain and the well W2 of transistor M2. In this manner, a body diode D4 of transistor M2 with a cathode coupled to the well W2 and an anode coupled to the drain of transistor M2 may be effectively present in transistor M2, and a body diode D3 may be shorted (e.g., effectively removing body diode D3 from the transistor M2 by shorting the well W2 to the source of transistor M2). In response to a logic high at well_sel2 of the switchable well 345, the switchable well 345 may open switch S3 and close switch S4. In this manner, the body diode D3 of transistor M2 with a cathode coupled to the well W2 and an anode coupled to the source of transistor M2 may be effectively present, and body diode D4 may be shorted (e.g., effectively removing body diode D4 from the transistor M4 by shorting the well W2 to the drain of transistor M2).

The controller 336 includes an input (labeled “FB” for feedback) coupled to the output 245 and an output coupled to a gate driver node (labeled “Gate_drv”), as illustrated. The controller 336 may be configured to drive the gate of transistor M1 or M2 from the Gate_drv node via the first multiplexer 332 or the second multiplexer 334, depending on a logic level of an input selection node (labeled “VIN_SEL”).

The first multiplexer 332 may include an output (labeled “Vg1”) coupled to a gate of transistor M1, a first input coupled to a power supply rail (labeled “pVdd” and configured with sufficiently high voltage to turn off transistor M1 and transistor M2), a second input coupled to the Gate_drv node, and a control input coupled to the VIN_SEL node, as illustrated. In this manner, a logic low at the VIN_SEL node may select the pVdd power supply rail (e.g., turning off transistor M1), and a logic high at the VIN_SEL node may select the Gate_drv node (e.g., controlling the gate of transistor M1 using the controller 336). The pVdd power supply rail may be provided by a maximum selection circuit (not illustrated) configured to select the maximum voltage among the VPH power supply rail voltage, VIN1 from SMPS1 210, or VIN2 from SMPS2 220 as the pVdd voltage.

The second multiplexer 334 may include an output (labeled “Vg2”) coupled to a gate of transistor M2, a first input coupled to the Gate_drv node, a second input coupled to the pVdd power supply rail, and a control input coupled to the VIN_SEL node, as illustrated. In this manner, a logic low at the VIN_SEL node may select the Gate_drv node (e.g., controlling the gate of transistor M2 using the controller 336), and a logic high at the VIN_SEL node may select the pVdd power supply rail (e.g., turning off transistor M2).

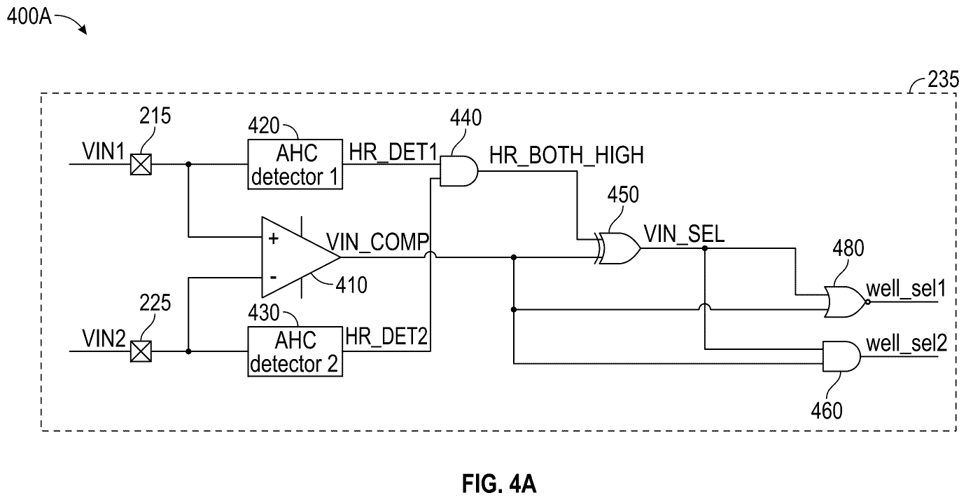

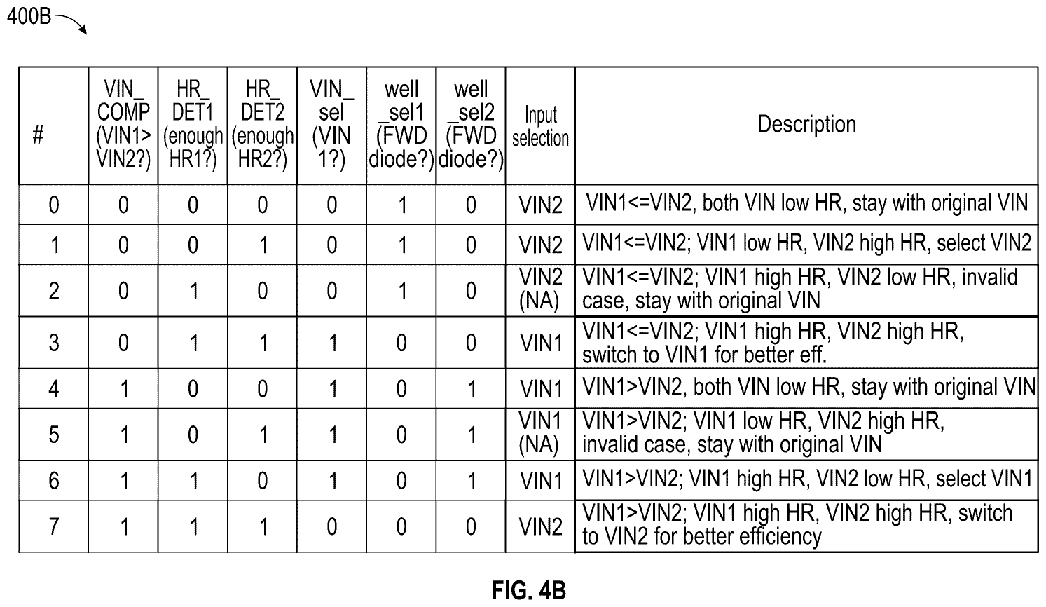

FIG. 4A is a circuit diagram 400A of an example logic circuit 235 included in the LDO regulator circuit 230 of FIG. 3, in accordance with certain aspects of the present disclosure. The logic circuit 235 may include a comparator 410, a first headroom detector 420 (labeled “AHC detector1,” where “AHC” stands for automatic headroom control), a second headroom detector 430 (labeled “AHC detector2”), a first logical AND gate 440, a logical XOR gate 450, a second logical AND gate 460, and a logical NOR gate 480.

The logic circuit 235 may include a first input (labeled “VIN1”) coupled to the input 215 of the LDO regulator circuit 230, a second input (labeled “VIN2”) coupled to the input 225 of the LDO regulator circuit 230. The logic circuit 235 may also include an output (labeled “well_sel1” in FIG. 4A) coupled to well_sel1 of the switchable well 340, an output (labeled “well_sel2” in FIG. 4A) coupled to well_sel2 of the switchable well 345, and an output (labeled “VIN_SEL” in FIG. 4A) coupled to the VIN_SEL node.

The comparator 410 may include a positive input coupled to the input 215 of the logic circuit 235, a negative input coupled to the input 225 of the logic circuit 235, and an output (labeled “VIN_COMP”) coupled to an input of the logical XOR gate 450, as illustrated. The comparator 410 may be configured to compare VIN1 and VIN2 (e.g., determine whether VIN1 is greater than VIN2) and output VIN_COMP based on the comparison.

The first headroom detector 420 may include an input coupled to the input 215 of the logic circuit 235 and an output (labeled “HR_DET1”) coupled to a first input of the first logical AND gate 440. The second headroom detector 430 may include an input coupled to the input 225 of the logic circuit 235 and an output (labeled “HR_DET2”) coupled to a second input of the first logical AND gate 440. The first logical AND gate 440 may include an output (labeled “HR_BOTH_HIGH”) coupled to another input of the logical XOR gate 450. The logical XOR gate 450 may include an output coupled to the VIN_SEL node. The second logical AND gate 460 may include a first input coupled to the output of the logical XOR gate 450, a second input coupled to the output of the comparator 410, and an output coupled to well_sel2 of the switchable well 345. The logical NOR gate 480 may include a first input coupled to the output of the logical XOR gate 450, a second input coupled to the output of the comparator 410, and an output coupled to well_sel1 of the switchable well 340.

FIG. 4B illustrates a table 400B that displays the operation of the logic circuit 235 of FIG. 4A in different scenarios, in accordance with certain aspects of the present disclosure.

In a scenario labeled #“0” in FIG. 4B, the logic circuit 235 may select VIN2 as the input power source for the LDO regulator circuit 230 with a logic low at the VIN_SEL node (e.g., VIN_sel (VIN1?)=0) when a voltage of VIN1 is lower than or equal to a voltage of VIN2 (e.g., VIN_COMP (VIN1>VIN2?)=0) and when both the voltage of VIN1 and the voltage of VIN2 have insufficient headroom (e.g., HR_DET1 (enough HR1?)=0 and HR_DET2 (enough HR2?)=0). In other words, neither VIN1 nor VIN2 has sufficient headroom for the desired output voltage, so the logic circuit 235 will select the higher voltage of VIN2. In this scenario, according to the circuit diagram 400A of FIG. 4A and the table 400B of FIG. 4B, well_sel1 may be logic high (e.g., well_sel1 (FWD diode?)=1), and well_sel2 may be logic low (e.g., well_sel2 (FWD diode?)=0). As a result, the logic circuit 235 may control the switchable well 340 (e.g., by opening switch S1 and closing switch S2) such that transistor M1 has a reverse-blocking body diode D1 (e.g., to effectively prevent current flow from the output 245 to the input 215) and may control the switchable well 345 (e.g., by closing switch S3 and opening switch S4) such that transistor M2 has a body diode D4 (but current flows from the input 225 through a channel of transistor M2 according to the control signal on the Gate_drv node).

In a scenario labeled #“1” in FIG. 4B, the logic circuit 235 may select VIN2 as the input power source for the LDO regulator circuit 230 with a logic low at the VIN_SEL node (e.g., VIN_sel (VIN1?)=0) when a voltage of VIN1 is lower than or equal to a voltage of VIN2 (e.g., VIN_COMP (VIN1>VIN2?)=0), when the voltage of VIN1 has insufficient headroom (e.g., HR_DET1 (enough HR1?)=0), and when the voltage of VIN2 has sufficient headroom (e.g., HR_DET2 (enough HR2?)=1). In other words, VIN2 is the input that provides sufficient headroom for the desired output voltage and will be selected by the logic circuit 235. In this scenario, according to the circuit diagram 400A of FIG. 4A and the table 400B of FIG. 4B, well_sel1 may be logic high (e.g., well_sel1 (FWD diode?)=1), and well_sel2 may be logic low (e.g., well_sel2 (FWD diode?)=0). As a result, the logic circuit 235 may control the switchable well 340 (e.g., by opening switch S1 and closing switch S2) such that transistor M1 has a reverse-blocking body diode D1 from the output 245 to the input 215 and may control the switchable well 345 (e.g., by closing switch S3 and opening switch S4) such that transistor M2 has a body diode D4 (but current flows from the input 225 through the channel of transistor M2 according to the control signal on the Gate_drv node).

In a scenario labeled #“2” in FIG. 4B, the logic circuit 235 may select VIN2 for the LDO regulator circuit 230 with a logic low at the VIN_SEL node (e.g., VIN_sel (VIN1?)=0) when a voltage of VIN1 is lower than or equal to a voltage of VIN2 (e.g., VIN_COMP (VIN1>VIN2?)=0), when the voltage of VIN1 has sufficient headroom (e.g., HR_DET1 (enough HR1?)=1), and when the voltage of VIN2 has insufficient headroom (e.g., HR_DET2 (enough HR2?)=0). This scenario is invalid, as the voltage at VIN1 is less than or equal to VIN2, but VIN1 supposedly has sufficient headroom for the load 240 while VIN2 has insufficient headroom, and thus, the logic circuit 235 may default to the originally selected input (e.g., VIN2). In this scenario, well_sel1 may be logic high (e.g., well_sel1 (FWD diode?)=1), and well_sel2 may be logic low (e.g., well_sel2 (FWD diode?)=0), with the same results for the switchable wells 340, 345 as described above for scenario #s 0 and 1.

In a scenario labeled #“3” in FIG. 4B, the logic circuit 235 may select VIN1 as the input power source for the LDO regulator circuit 230 with a logic high at the VIN_SEL node (e.g., VIN_sel (VIN1?)=1) when a voltage of VIN1 is lower than or equal to a voltage of VIN2 (e.g., VIN_COMP (VIN1>VIN2?)=0), when the voltage of VIN1 has sufficient headroom (e.g., HR_DET1 (enough HR1?)=1), and when the voltage of VIN2 also has sufficient headroom (e.g., HR_DET2 (enough HR2?)=1). In other words, both VIN1 and VIN2 provide sufficient headroom for the desired output voltage, and thus, the logic circuit 235 will select VIN1, because VIN1 has a lower voltage and will therefore lead to higher power supply efficiency than VIN2. In this scenario, according to the circuit diagram 400A of FIG. 4A and the table 400B of FIG. 4B, well_sel1 may be logic low (e.g., well_sel1 (FWD diode?)=0), and well_sel2 may be logic low (e.g., well_sel2 (FWD diode?)=0). As a result, the logic circuit 235 may control the switchable well 340 (e.g., by closing switch S1 and opening switch S2) such that transistor M1 has a body diode D2 (but current flows from the input 215 through the channel of transistor M1 according to the control signal on the Gate_drv node) and may control the switchable well 345 (e.g., by closing switch S3 and opening switch S4) such that transistor M2 has a forward-blocking body diode D4 from the input 225 to the output 245 (e.g., to effectively prevent current flow from the input 225 to the output 245).

In a scenario labeled #“4” in FIG. 4B, the logic circuit 235 may select VIN1 as the input power source for the LDO regulator circuit 230 with a logic high at the VIN_SEL node (e.g., VIN_sel (VIN1?)=1) when a voltage of VIN1 is greater than a voltage of VIN2 (e.g., VIN_COMP (VIN1>VIN2?)=1), when the voltage of VIN1 has insufficient headroom (e.g., HR_DET1 (enough HR1?)=0), and when the voltage of VIN2 has insufficient headroom (e.g., HR_DET2 (enough HR2?)=0). In other words, neither VIN1 nor VIN2 has sufficient headroom for the desired output voltage, so the logic circuit 235 will select the higher voltage of VIN1. In this scenario, according to the circuit diagram 400A of FIG. 4A and the table 400B of FIG. 4B, well_sel1 may be logic low (e.g., well_sel1 (FWD diode?)=0), and well_sel2 may be logic high (e.g., well_sel2 (FWD diode?)=1). As a result, the logic circuit 235 may control the switchable well 340 (e.g., by closing switch S1 and opening switch S2) such that transistor M1 has a body diode D2 (but current flows from the input 215 through the channel of transistor M1 according to the control signal on the Gate_drv node) and may control the switchable well 345 (e.g., by opening switch S3 and closing switch S4) such that transistor M2 has a reverse-blocking body diode D3 from the output 245 to the input 225.

In a scenario labeled #“5” in FIG. 4B, the logic circuit 235 may select VIN1 for the LDO regulator circuit 230 with a logic high at the VIN_SEL node (e.g., VIN_sel (VIN1?)=1) when a voltage of VIN1 is greater than a voltage of VIN2 (e.g., VIN_COMP (VIN1>VIN2?)=1), when the voltage of VIN1 has insufficient headroom (e.g., HR_DET1 (enough HR1?)=0), and when the voltage of VIN2 has sufficient headroom (e.g., HR_DET2 (enough HR2?)=0). This scenario is invalid, as the voltage at VIN1 is greater than VIN2, but VIN2 supposedly has sufficient headroom for the load 240 while VIN1 has insufficient headroom, and thus, the logic circuit 235 may default to the originally selected input (e.g., VIN1). In this scenario, well_sel1 may be logic low (e.g., well_sel1 (FWD diode?)=0), and well_sel2 may be logic high (e.g., well_sel2 (FWD diode?)=1), with the same results for the switchable wells 340, 345 as described above for scenario #4.

In a scenario labeled #“6” in FIG. 4B, the logic circuit 235 may select VIN1 as the input power source for the LDO regulator circuit 230 with a logic high at the VIN_SEL node (e.g., VIN_sel (VIN1?)=1) when a voltage of VIN1 is greater than a voltage of VIN2 (e.g., VIN_COMP (VIN1>VIN2?)=1), when the voltage of VIN1 has sufficient headroom (e.g., HR_DET1 (enough HR1?)=1), and when the voltage of VIN2 has insufficient headroom (e.g., HR_DET2 (enough HR2?)=0). In other words, VIN1 is the input that provides sufficient headroom for the desired output voltage and will be selected by the logic circuit 235. In this scenario, according to the circuit diagram 400A of FIG. 4A and the table 400B of FIG. 4B, well_sel1 may be logic low (e.g., well_sel1 (FWD diode?)=0), and well_sel2 may be logic high (e.g., well_sel2 (FWD diode?)=1). As a result, the logic circuit 235 may control the switchable well 340 (e.g., by closing switch S1 and opening switch S2) such that transistor M1 has a body diode D2 (but current flows from the input 215 through the channel of transistor M1 according to the control signal on the Gate_drv node) and may control the switchable well 345 (e.g., by opening switch S3 and closing switch S4) such that transistor M2 has a reverse-blocking body diode D3 from the output 245 to the input 225 (e.g., to effectively prevent current flow from the output 245 to the input 225).

In a scenario labeled #“7” in FIG. 4B, the logic circuit 235 may select VIN2 as the input power source for the LDO regulator circuit 230 with a logic low at the VIN_SEL node (e.g., VIN_sel (VIN1?)=0) when a voltage of VIN1 is greater than a voltage of VIN2 (e.g., VIN_COMP (VIN1>VIN2?)=1), when the voltage of VIN1 has sufficient headroom (e.g., HR_DET1 (enough HR1?)=1), and when the voltage of VIN2 also has sufficient headroom (e.g., HR_DET2 (enough HR2?)=1). In other words, both VIN1 and VIN2 provide sufficient headroom for the desired output voltage, and thus, the logic circuit 235 will select VIN2, because VIN2 has a lower voltage and will therefore lead to higher power supply efficiency than VIN1. In this scenario, according to the circuit diagram 400A of FIG. 4A and the table 400B of FIG. 4B, well_sel1 may be logic low (e.g., well_sel1 (FWD diode?)=0), and well_sel2 may be logic low (e.g., well_sel2 (FWD diode?)=0). As a result, the logic circuit 235 may control the switchable well 340 (e.g., by closing switch S1 and opening switch S2) such that transistor M1 has a forward-blocking body diode D2 from the input 215 to the output 245 and may control the switchable well 345 (e.g., by closing switch S3 and opening switch S4) such that transistor M2 has a body diode D4 (but current flows from the input 225 through the channel of transistor M2 according to the control signal on the Gate_drv node).

### Example Operations for Supplying Power

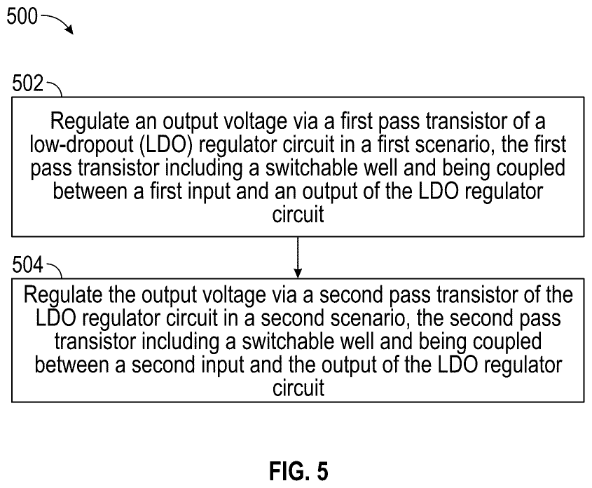

FIG. 5 is a flow diagram illustrating example operations 500 for supplying power, in accordance with certain aspects of the present disclosure. The operations 500 may be performed, for example, by a power supply circuit, such as the LDO regulator circuit 230 of FIGS. 2 and 3.

The operations 500 may include, at block 502, regulating an output voltage via a first pass transistor (e.g., transistor M1) of an LDO regulator circuit (e.g., LDO regulator circuit 230) in a first scenario. The first pass transistor may include a switchable well (e.g., switchable well 340) and be coupled between a first input (e.g., input 215) and an output (e.g., output 245) of the LDO regulator circuit.

At block 504, the operations 500 may include regulating the output voltage via a second pass transistor (e.g., transistor M2) of the LDO regulator circuit in a second scenario. The second pass transistor may include a switchable well (e.g., switchable well 345) and be coupled between a second input (e.g., input 225) and the output of the LDO regulator circuit.

In certain aspects, regulating the output voltage in the first scenario at block 502 may include driving a gate of the first pass transistor from a gate driver node (e.g., the Gate_drv node), regulating the output voltage in the second scenario at block 504 may include driving a gate of the second pass transistor from the gate driver node, and the operations 500 may further include selectively routing the gate driver node from the gate of the first pass transistor to the gate of the second pass transistor. In these aspects, the operations 500 may further include comparing a voltage of the first input (e.g., VIN1) and a voltage of the second input (e.g., VIN2), and determining whether at least one of the voltage of the first input or the voltage of the second input has sufficient headroom for the output voltage (e.g., HR_DET1 (enough HR1?)=1 and/or HR_DET2 (enough HR2?)=1). The selectively routing may be based on at least one of the comparison or the determination.

In certain aspects, the first scenario may include: (i) a voltage of the first input being lower than a voltage of the second input (e.g., VIN_COMP (VIN1>VIN2?)=0) and (ii) both the voltage of the first input and the voltage of the second input having sufficient headroom (e.g., HR_DET1 (enough HR1?)=1 and HR_DET2 (enough HR2?)=1). In these aspects, regulating the output voltage in the first scenario at block 502 may include controlling the switchable well of the second pass transistor with a logic low (e.g., well_sel2 (FWD diode?)=0) such that the second pass transistor has a forward-blocking body diode (e.g., forward-blocking body diode D4) from the second input to the output of the LDO regulator circuit.

In certain aspects, the second scenario may include: (i) a voltage of the second input being lower than a voltage of the first input (e.g., VIN_COMP (VIN1>VIN2?)=1) and (ii) both the voltage of the first input and the voltage of the second input having sufficient headroom (e.g., HR_DET1 (enough HR1?)=1 and HR_DET2 (enough HR2?)=1). In these aspects, regulating the output voltage in the second scenario at block 504 may include controlling the switchable well of the first pass transistor with a logic low (e.g., well_sel1 (FWD diode?)=0) such that the first pass transistor has a forward-blocking body diode (e.g., forward-blocking body diode D2) from the first input to the output of the LDO regulator circuit.

In certain aspects, the first scenario may include a voltage of the first input being higher than a voltage of the second input (e.g., VIN_COMP (VIN1>VIN2?)=1), the voltage of the first input having sufficient headroom (e.g., HR_DET1 (enough HR1?)=1), and the voltage of the second input having insufficient headroom (e.g., HR_DET2 (enough HR2?)=0). In these aspects, regulating the output voltage in the first scenario at block 502 may include controlling the switchable well of the second pass transistor with a logic high (e.g., well_sel2 (FWD diode?)=1) such that the second pass transistor has a reverse-blocking body diode (e.g., reverse-blocking body diode D3) from the output to the second input of the LDO regulator circuit.

In certain aspects, the second scenario may include a voltage of the second input being higher than a voltage of the first input (e.g., VIN_COMP (VIN1>VIN2?)=0), the voltage of the second input having sufficient headroom (e.g., HR_DET2 (enough HR2?)=1), and the voltage of the first input having insufficient headroom (e.g., HR_DET1 (enough HR1?)=0). In these aspects, regulating the output voltage in the second scenario at block 504 may include controlling the switchable well of the first pass transistor with a logic high (e.g., well_sel1 (FWD diode?)=1) such that the first pass transistor has a reverse-blocking body diode (e.g., reverse-blocking body diode D1) from the output to the first input of the LDO regulator circuit.

### Example Aspects

In addition to the various aspects described above, specific combinations of aspects are within the scope of the disclosure, some of which are detailed below:

Aspect 1: A low-dropout (LDO) regulator circuit comprising: a first input; a second input; an output; a first pass transistor including a switchable well, a source coupled to the first input of the LDO regulator circuit, and a drain coupled to the output of the LDO regulator circuit; and a second pass transistor including a switchable well, a source coupled to the second input of the LDO regulator circuit, and a drain coupled to the output of the LDO regulator circuit.

Aspect 2: The LDO regulator circuit of Aspect 1, further comprising a logic circuit including: a first output coupled to a gate of the first pass transistor; and a second output coupled to a gate of the second pass transistor, wherein the logic circuit is configured to selectively couple the first output to a power supply rail or to a gate driver node and to selectively couple the second output to the gate driver node or to the power supply rail.

Aspect 3: The LDO regulator circuit of Aspect 2, wherein the logic circuit further includes: a first input coupled to the first input of the LDO regulator circuit; a second input coupled to the second input of the LDO regulator circuit; a third output coupled to a control input of the switchable well of the first pass transistor; and a fourth output coupled to a control input of the switchable well of the second pass transistor.

Aspect 4: The LDO regulator circuit of Aspect 3, wherein the logic circuit is configured to select the first input of the LDO regulator circuit with a logic high at an input selection node when a voltage of the first input is lower than a voltage of the second input and when both the voltage of the first input and the voltage of the second input have sufficient headroom.

Aspect 5: The LDO regulator circuit of Aspect 4, wherein the logic circuit is further configured to control the switchable well of the second pass transistor with a logic low at the fourth output of the logic circuit such that the second pass transistor has a forward-blocking body diode from the second input to the output of the LDO regulator circuit.

Aspect 6: The LDO regulator circuit according to any of Aspects 3-5, wherein the logic circuit is configured to select the second input of the LDO regulator circuit with a logic low at an input selection node when a voltage of the second input is lower than a voltage of the first input and when both the voltage of the first input and the voltage of the second input have sufficient headroom.

Aspect 7: The LDO regulator circuit of Aspect 6, wherein the logic circuit is further configured to control the switchable well of the first pass transistor with a logic low at the third output of the logic circuit such that the first pass transistor has a forward-blocking body diode from the first input to the output of the LDO regulator circuit.

Aspect 8: The LDO regulator circuit according to any of Aspects 3-7, wherein the logic circuit is configured to select the first input of the LDO regulator circuit with a logic high at an input selection node when a voltage of the first input is higher than a voltage of the second input, when the voltage of the first input has sufficient headroom, and when the voltage of the second input has insufficient headroom.

Aspect 9: The LDO regulator circuit of Aspect 8, wherein the logic circuit is further configured to control the switchable well of the second pass transistor with a logic high at the fourth output of the logic circuit such that the second pass transistor has a reverse-blocking body diode from the output to the second input of the LDO regulator circuit.

Aspect 10: The LDO regulator circuit according to any of Aspects 3-9, wherein the logic circuit is configured to select the second input of the LDO regulator circuit with a logic low at an input selection node when a voltage of the second input is higher than a voltage of the first input, when the voltage of the second input has sufficient headroom, and when the voltage of the first input has insufficient headroom.

Aspect 11: The LDO regulator circuit of Aspect 10, wherein the logic circuit is further configured to control the switchable well of the first pass transistor with a logic high at the third output of the logic circuit such that the first pass transistor has a reverse-blocking body diode from the output to the first input of the LDO regulator circuit.

Aspect 12: The LDO regulator circuit according to any of Aspects 3-11, wherein the logic circuit comprises: a comparator including a positive input coupled to the first input of the logic circuit and a negative input coupled to the second input of the logic circuit; a first headroom detector including an input coupled to the first input of the logic circuit; a second headroom detector including an input coupled to the second input of the logic circuit; a first logical AND gate including a first input coupled to an output of the first headroom detector and a second input coupled to an output of the second headroom detector; a logical XOR gate including a first input coupled to an output of the first logical AND gate, a second input coupled to an output of the comparator, and an output coupled to an input selection node; a second logical AND gate including a first input coupled to the output of the logical XOR gate, a second input coupled to the output of the comparator, and an output coupled to the fourth output of the logic circuit; and a logical NOR gate including a first input coupled to the output of the logical XOR gate, a second input coupled to the output of the comparator, and an output coupled to the third output of the logic circuit.

Aspect 13: The LDO regulator circuit according to any of Aspects 1-12, wherein the switchable well of the first pass transistor is configured such that: a logic low at a control input of the switchable well is configured to close a first switch between the source and a well of the first pass transistor and to effectively leave a first body diode with a cathode coupled to the well and an anode coupled to the drain of the first pass transistor; and a logic high at the control input of the switchable well is configured to close a second switch between the drain and the well of the first pass transistor and to effectively leave a second body diode with a cathode coupled to the well and an anode coupled to the source of the first pass transistor.

Aspect 14: The LDO regulator circuit according to any of Aspects 1-13, further comprising: a first multiplexer including an output coupled to a gate of the first pass transistor, a first input coupled to a power supply rail, a second input coupled to a gate driver node, and a control input coupled to an input selection node, wherein a logic low at the input selection node is configured to select the first input of the first multiplexer and wherein a logic high at the input selection node is configured to select the second input of the first multiplexer; and a second multiplexer including an output coupled to a gate of the second pass transistor, a first input coupled to the gate driver node, a second input coupled to the power supply rail, and a control input coupled to the input selection node, wherein a logic low at the input selection node is configured to select the first input of the second multiplexer and wherein a logic high at the input selection node is configured to select the second input of the second multiplexer.

Aspect 15: A method of supplying power, comprising: regulating an output voltage via a first pass transistor of a low-dropout (LDO) regulator circuit in a first scenario, the first pass transistor including a switchable well and being coupled between a first input and an output of the LDO regulator circuit; and regulating the output voltage via a second pass transistor of the LDO regulator circuit in a second scenario, the second pass transistor including a switchable well and being coupled between a second input and the output of the LDO regulator circuit.

Aspect 16: The method of Aspect 15, wherein: regulating the output voltage in the first scenario comprises driving a gate of the first pass transistor from a gate driver node; regulating the output voltage in the second scenario comprises driving a gate of the second pass transistor from the gate driver node; and the method further comprises selectively routing the gate driver node from the gate of the first pass transistor to the gate of the second pass transistor.

Aspect 17: The method of Aspect 16, further comprising: comparing a voltage of the first input and a voltage of the second input; and determining whether at least one of the voltage of the first input or the voltage of the second input has sufficient headroom for the output voltage, wherein the selectively routing is based on at least one of the comparison or the determination.

Aspect 18: The method according to any of Aspects 15-17, wherein: the first scenario includes a voltage of the first input being lower than a voltage of the second input and both the voltage of the first input and the voltage of the second input having sufficient headroom; and regulating the output voltage in the first scenario comprises controlling the switchable well of the second pass transistor with a logic low such that the second pass transistor has a forward-blocking body diode from the second input to the output of the LDO regulator circuit.

Aspect 19: The method according to any of Aspects 15-18, wherein: the second scenario includes a voltage of the second input being lower than a voltage of the first input and both the voltage of the first input and the voltage of the second input having sufficient headroom; and regulating the output voltage in the second scenario comprises controlling the switchable well of the first pass transistor with a logic low such that the first pass transistor has a forward-blocking body diode from the first input to the output of the LDO regulator circuit.

Aspect 20: The method according to any of Aspects 15, 16, 17, and 19, wherein: the first scenario includes a voltage of the first input being higher than a voltage of the second input, the voltage of the first input having sufficient headroom, and the voltage of the second input having insufficient headroom; and regulating the output voltage in the first scenario comprises controlling the switchable well of the second pass transistor with a logic high such that the second pass transistor has a reverse-blocking body diode from the output to the second input of the LDO regulator circuit.

Aspect 21: The method according to any of Aspects 15, 16, 17, 18, and 20, wherein: the second scenario includes a voltage of the second input being higher than a voltage of the first input, the voltage of the second input having sufficient headroom, and the voltage of the first input having insufficient headroom; and regulating the output voltage in the second scenario comprises controlling the switchable well of the first pass transistor with a logic high such that the first pass transistor has a reverse-blocking body diode from the output to the first input of the LDO regulator circuit.

### Additional Considerations

The various operations of methods described above may be performed by any suitable means capable of performing the corresponding functions. The means may include various hardware and/or software component(s) and/or module(s), including, but not limited to a circuit, an application-specific integrated circuit (ASIC), or a processor. Generally, where there are operations illustrated in figures, those operations may have corresponding counterpart means-plus-function components with similar numbering.

As used herein, the term “determining” encompasses a wide variety of actions. For example, “determining” may include calculating, computing, processing, deriving, investigating, looking up (e.g., looking up in a table, a database, or another data structure), ascertaining, and the like. Also, “determining” may include receiving (e.g., receiving information), accessing (e.g., accessing data in a memory), and the like. Also, “determining” may include resolving, selecting, choosing, establishing, and the like.

As used herein, a phrase referring to “at least one of” a list of items refers to any combination of those items, including single members. As an example, “at least one of: a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

It is to be understood that the claims are not limited to the precise configuration and components illustrated above. Various modifications, changes, and variations may be made in the arrangement, operation, and details of the methods and apparatus described above without departing from the scope of the claims.

What is claimed is:

1. A low-dropout (LDO) regulator circuit comprising:
a first input;
a second input;
an output;
a first pass transistor including a switchable well, a source coupled to the first input of the LDO regulator circuit, and a drain coupled to the output of the LDO regulator circuit; and
a second pass transistor including a switchable well, a source coupled to the second input of the LDO regulator circuit, and a drain coupled to the output of the LDO regulator circuit.

2. The LDO regulator circuit of claim 1, further comprising a logic circuit including:
a first output coupled to a gate of the first pass transistor; and
a second output coupled to a gate of the second pass transistor, wherein the logic circuit is configured to selectively couple the first output to a power supply rail or to a gate driver node and to selectively couple the second output to the gate driver node or to the power supply rail.

3. The LDO regulator circuit of claim 2, wherein the logic circuit further includes:
a first input coupled to the first input of the LDO regulator circuit;
a second input coupled to the second input of the LDO regulator circuit;
a third output coupled to a control input of the switchable well of the first pass transistor; and
a fourth output coupled to a control input of the switchable well of the second pass transistor.

4. The LDO regulator circuit of claim 3, wherein the logic circuit is configured to select the first input of the LDO regulator circuit with a logic high at an input selection node when a voltage of the first input is lower than a voltage of the second input and when both the voltage of the first input and the voltage of the second input have sufficient headroom.

5. The LDO regulator circuit of claim 4, wherein the logic circuit is further configured to control the switchable well of the second pass transistor with a logic low at the fourth output of the logic circuit such that the second pass transistor has a forward-blocking body diode from the second input to the output of the LDO regulator circuit.

6. The LDO regulator circuit of claim 3, wherein the logic circuit is configured to select the second input of the LDO regulator circuit with a logic low at an input selection node when a voltage of the second input is lower than a voltage of the first input and when both the voltage of the first input and the voltage of the second input have sufficient headroom.

7. The LDO regulator circuit of claim 6, wherein the logic circuit is further configured to control the switchable well of the first pass transistor with a logic low at the third output of the logic circuit such that the first pass transistor has a forward-blocking body diode from the first input to the output of the LDO regulator circuit.

8. The LDO regulator circuit of claim 3, wherein the logic circuit is configured to select the first input of the LDO regulator circuit with a logic high at an input selection node when a voltage of the first input is higher than a voltage of the second input, when the voltage of the first input has sufficient headroom, and when the voltage of the second input has insufficient headroom.

9. The LDO regulator circuit of claim 8, wherein the logic circuit is further configured to control the switchable well of the second pass transistor with a logic high at the fourth output of the logic circuit such that the second pass transistor has a reverse-blocking body diode from the output to the second input of the LDO regulator circuit.

10. The LDO regulator circuit of claim 3, wherein the logic circuit is configured to select the second input of the LDO regulator circuit with a logic low at an input selection node when a voltage of the second input is higher than a voltage of the first input, when the voltage of the second input has sufficient headroom, and when the voltage of the first input has insufficient headroom.

11. The LDO regulator circuit of claim 10, wherein the logic circuit is further configured to control the switchable well of the first pass transistor with a logic high at the third output of the logic circuit such that the first pass transistor has a reverse-blocking body diode from the output to the first input of the LDO regulator circuit.

12. The LDO regulator circuit of claim 3, wherein the logic circuit comprises:
a comparator including a positive input coupled to the first input of the logic circuit and a negative input coupled to the second input of the logic circuit;
a first headroom detector including an input coupled to the first input of the logic circuit;
a second headroom detector including an input coupled to the second input of the logic circuit;
a first logical AND gate including a first input coupled to an output of the first headroom detector and a second input coupled to an output of the second headroom detector;
a logical XOR gate including a first input coupled to an output of the first logical AND gate, a second input coupled to an output of the comparator, and an output coupled to an input selection node;
a second logical AND gate including a first input coupled to the output of the logical XOR gate, a second input coupled to the output of the comparator, and an output coupled to the fourth output of the logic circuit; and
a logical NOR gate including a first input coupled to the output of the logical XOR gate, a second input coupled to the output of the comparator, and an output coupled to the third output of the logic circuit.

13. The LDO regulator circuit of claim 1, wherein the switchable well of the first pass transistor is configured such that:
a logic low at a control input of the switchable well is configured to close a first switch between the source and a well of the first pass transistor and to effectively leave a first body diode with a cathode coupled to the well and an anode coupled to the drain of the first pass transistor; and
a logic high at the control input of the switchable well is configured to close a second switch between the drain and the well of the first pass transistor and to effectively leave a second body diode with a cathode coupled to the well and an anode coupled to the source of the first pass transistor.

14. The LDO regulator circuit of claim 1, further comprising:
a first multiplexer including an output coupled to a gate of the first pass transistor, a first input coupled to a power supply rail, a second input coupled to a gate driver node, and a control input coupled to an input selection node, wherein a logic low at the input selection node is configured to select the first input of the first multiplexer and wherein a logic high at the input selection node is configured to select the second input of the first multiplexer; and
a second multiplexer including an output coupled to a gate of the second pass transistor, a first input coupled to the gate driver node, a second input coupled to the power supply rail, and a control input coupled to the input selection node, wherein a logic low at the input selection node is configured to select the first input of the second multiplexer and wherein a logic high at the input selection node is configured to select the second input of the second multiplexer.

15. A method of supplying power, comprising:
regulating an output voltage via a first pass transistor of a low-dropout (LDO) regulator circuit in a first scenario, the first pass transistor including a switchable well and being coupled between a first input and an output of the LDO regulator circuit; and
regulating the output voltage via a second pass transistor of the LDO regulator circuit in a second scenario, the second pass transistor including a switchable well and being coupled between a second input and the output of the LDO regulator circuit.

16. The method of claim 15, wherein:
regulating the output voltage in the first scenario comprises driving a gate of the first pass transistor from a gate driver node;
regulating the output voltage in the second scenario comprises driving a gate of the second pass transistor from the gate driver node;
the method further comprises:
selectively routing the gate driver node from the gate of the first pass transistor to the gate of the second pass transistor;
comparing a voltage of the first input and a voltage of the second input; and
determining whether at least one of the voltage of the first input or the voltage of the second input has sufficient headroom for the output voltage; and
the selectively routing is based on at least one of the comparison or the determination.

17. The method of claim 15, wherein:
the first scenario includes a voltage of the first input being lower than a voltage of the second input and both the voltage of the first input and the voltage of the second input having sufficient headroom; and
regulating the output voltage in the first scenario comprises controlling the switchable well of the second pass transistor with a logic low such that the second pass transistor has a forward-blocking body diode from the second input to the output of the LDO regulator circuit.

18. The method of claim 15, wherein:
the second scenario includes a voltage of the second input being lower than a voltage of the first input and both the voltage of the first input and the voltage of the second input having sufficient headroom; and
regulating the output voltage in the second scenario comprises controlling the switchable well of the first pass transistor with a logic low such that the first pass transistor has a forward-blocking body diode from the first input to the output of the LDO regulator circuit.

19. The method of claim 15, wherein:
the first scenario includes a voltage of the first input being higher than a voltage of the second input, the voltage of the first input having sufficient headroom, and the voltage of the second input having insufficient headroom; and
regulating the output voltage in the first scenario comprises controlling the switchable well of the second pass transistor with a logic high such that the second pass transistor has a reverse-blocking body diode from the output to the second input of the LDO regulator circuit.

20. The method of claim 15, wherein:
the second scenario includes a voltage of the second input being higher than a voltage of the first input, the voltage of the second input having sufficient headroom, and the voltage of the first input having insufficient headroom; and
regulating the output voltage in the second scenario comprises controlling the switchable well of the first pass transistor with a logic high such that the first pass transistor has a reverse-blocking body diode from the output to the first input of the LDO regulator circuit.
